(19) United States
(12) Patent Application Publication
(10) Pub. No.: US 2026/0101506 A1
(43) Pub. Date: Apr. 9, 2026

(54) Method and System for Enhancing Etch Efficiency in 3D NAND Using Silicon/Silicon-Germanium Stack Replacement

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/909,968

(22) Filed: Oct. 9, 2024

(51) Int. Cl. H10B 41/35; H10B 41/20; H10B 43/20; H10B 43/35

(52) U.S. Cl. CPC H10B 41/35; H10B 41/20; H10B 43/20; H10B 43/35

(57) ABSTRACT

This invention provides a method for improving the fabrication of 3D NAND devices by replacing the conventional oxide-nitride-oxide-nitride (ONON) stack with a silicon (Si) and silicon-germanium (SiGe) stack. This approach simplifies and accelerates the etching process by leveraging the lower bond strength and higher reactivity of Si and SiGe, while enabling effective layer replacement for electrical isolation and gate formation. The method enhances manufacturability and scalability of high-density 3D NAND devices.

### FIELD OF THE INVENTION

The field of the invention relates to semiconductor fabrication processes, and more specifically, to methods for forming vertical storage units in 3D NAND memory devices. In particular, the invention involves using a silicon (Si) and silicon-germanium (SiGe) stack as a replacement for the conventional oxide-nitride-oxide-nitride (ONON) and oxide-polysilicon-oxide-polysilicon (OPOP) stacks to improve the efficiency of the etching process. This invention addresses the challenges of high aspect ratio (HAR) etching in complex multilayer structures, with the goal of enabling higher scalability and manufacturability in 3D NAND memory devices.

### BACKGROUND

In the fabrication of 3D NAND devices using an ONON stack and to less extent an OPOP stack, the increasing number of layers, now exceeding 200 pairs with a stack depth over 10 micrometers, presents significant challenges in the etching process, particularly for channel hole formation. As the stack height increases, maintaining a uniform etching profile becomes increasingly difficult, and various defects can arise, negatively impacting device performance and yield.

One of the major challenges is pattern distortion, where the profiles of the channel holes deviate from the intended vertical design. As the etch progresses through the deep ONON stack, profile bowing can occur, causing the channel walls to widen at specific depths. This deviation compromises the structural integrity of the channel and leads to variations in the device performance. Such CD variations are particularly problematic in 3D NAND because they can result in inconsistent device performance across the wafer. Furthermore, as the stack depth increases, the etching process becomes slower. The deeper the stack, the more difficult it is for chemically reactive neutrals and ions to reach the bottom of the high aspect ratio (HAR) structures. This limitation not only slows the etch process but can also lead to risks of incomplete etching at the bottom of the structure, further compromising the channel formation.

Another critical issue is titling of the channel holes caused by nonuniformity of plasma within a process chamber. Even slight deviations from verticality can introduce significant variability in the electrical properties of the memory cells, reducing device reliability and yield.

At a fundamental level, the ONON stack presents difficulties for etching due to the nature of the materials used. The silicon oxide and silicon nitride layers in the ONON structure are characterized by strong bonds that are inherently difficult to break during the etching process. These materials require high-energy ions to overcome the bond strength, and as the aspect ratio increases with deeper stacks, delivering enough energy to the bottom of the structure becomes increasingly challenging. This fundamental difficulty exacerbates the slow etching and less ideal profile formation in HAR structures, further limiting the scalability of 3D NAND technology. It is in this context, there is a pressing need to redesign the materials of the stack to mitigate challenges and risks associated with the current mainstream ONON stack for 3D NAND.

### SUMMARY OF THE INVENTION

This invention relates to the use of a silicon (Si) and silicon-germanium (SiGe) stack to replace the conventional oxide-nitride-oxide-nitride (ONON) stack in the 3D NAND fabrication process, with the primary objective of making the etching process more efficient. The key motivation is to address the growing challenges of etching the ONON stack, which becomes increasingly difficult due to the strong Si—O and Si—N bonds, requiring more energy and slowing the etching process as device complexity increases. The Si/SiGe stack offers a solution by providing materials with weaker bonds that are easier to etch, and that react more efficiently with etching chemistries, such as those using halogens, resulting in faster etch rates and more efficient removal of material, particularly in high aspect ratio (HAR) structures.

In some embodiments, this invention involves a double replacement of layers to achieve both electrical isolation and gate formation. The SiGe layers are replaced with silicon oxide, which serves as electrical isolation, while the Si layers are replaced with metal layers such as tungsten or molybdenum to form the gate electrodes. This dual replacement simplifies the etching processes, making it more efficient and scalable for advanced 3D NAND devices.

In some implementations, the Si/SiGe stack may be deposited using epitaxy, providing high-quality crystalline growth. However, since the Si/SiGe layers function as dummy layers that will be replaced, PECVD can be a more cost-effective solution. Unlike in logic processes or 3D DRAM, where the Si and or SiGe material serves as a critical component (e.g., as transistor channels), defects like dislocations are less of a concern in this application. This flexibility in choosing deposition methods helps lower manufacturing costs without compromising the final device performance.

In some implementations, the Ge concentration in the SiGe is in a range of 10 to 90%. The stack may include 10 to 1000 layers of Si/SiGe pairs.

By using a Si/SiGe stack and incorporating double replacement of layers, this invention offers a significant improvement in the manufacturability of 3D NAND devices, particularly by simplifying and accelerating the etching process. This innovation enables the continued scaling of 3D NAND technology, while maintaining critical electrical isolation and metal gate formation, thus addressing a major bottleneck in the existing fabrication process.

### BRIEF DESCRIPTIONS OF THE DRAWINGS

The embodiments of the invention are further explained with reference to the following drawings:

FIG. 1A: A schematic illustration showing both cross-sectional and top views at the stack formation step.

FIG. 1B: A schematic illustration showing both cross-sectional and top views at the channel formation step.

FIG. 1C: A schematic illustration showing both cross-sectional and top views during slit formation, where the SiGe layers are removed.

FIG. 1D: A schematic illustration showing both cross-sectional and top views during slit formation, where the oxide layers are deposited to replace the SiGe layers.

FIG. 1E: A schematic illustration showing both cross-sectional and top views during the gate formation, where the Si layers are replaced by metal layers.

FIG. 2: A flowchart depicting an exemplary process flow for forming vertical storage units using a dual replaceable Si/SiGe stack.

### DETAILED DESCRIPTION

The following detailed description provides specific embodiments to aid in understanding the invention. While particular examples are presented for clarity, various modifications and changes that fall within the scope of the appended claims are possible. Common processes, systems, and components are not described exhaustively in order to focus on key aspects of the invention.

### Definition

3D NAND: A type of non-volatile flash memory where memory cells are stacked vertically to increase density.

Silicon (Si) and Silicon-Germanium (SiGe) Stack: Alternating layers of silicon and silicon-germanium used in the fabrication process, replacing the conventional ONON stack.

Oxide-Nitride-Oxide-Nitride (ONON) Stack: A conventional multilayer stack used in 3D NAND fabrication, consisting of alternating layers of silicon oxide (SiO₂) and silicon nitride (Si₃N₄).

Oxide-Polysilicon-Oxide-Polysilicon (OPOP) Stack: A conventional multilayer stack used in 3D NAND fabrication, consisting of alternating layers of silicon oxide (SiO₂) and polysilicon.

High Aspect Ratio (HAR) Structures: Deep, narrow features such as trenches or holes in the semiconductor fabrication process, where the height is much greater than the width.

Etching: A process used in semiconductor manufacturing to selectively remove layers of material to form desired structures.

Plasma-Enhanced Chemical Vapor Deposition (PECVD): A technique used to deposit thin films from a gas state to a solid state on a substrate, often at lower temperatures.

Epitaxy: A method used to grow a crystalline layer on a substrate, typically to achieve high-quality crystalline structures.

Electrical Isolation Layer: A layer, typically made of silicon oxide, that electrically separates components within the 3D NAND structure.

Gate Formation: The process of creating metal gate electrodes, which control the flow of current in memory cells.

Slit Formation: The process of creating openings in the stack to replace the SiGe and Si layers with electrical isolation and metal gate layers.

Charge Storage Layer: A layer typically made of silicon nitride, used to store electrical charges in memory cells.

Atomic Layer Deposition (ALD): A thin-film deposition process used to deposit layers of material with atomic-level precision.

Transformer Coupled Plasma ( TCP): A type of plasma etching system that uses electromagnetic fields to generate high-density plasma for etching processes.

Selective Etching: A process where one material is etched at a much faster rate than another, allowing for targeted removal of specific layers.

Dummy Layer: A temporary layer, such as Si and SiGe in this invention, which is used during fabrication but is later removed and replaced by another material.

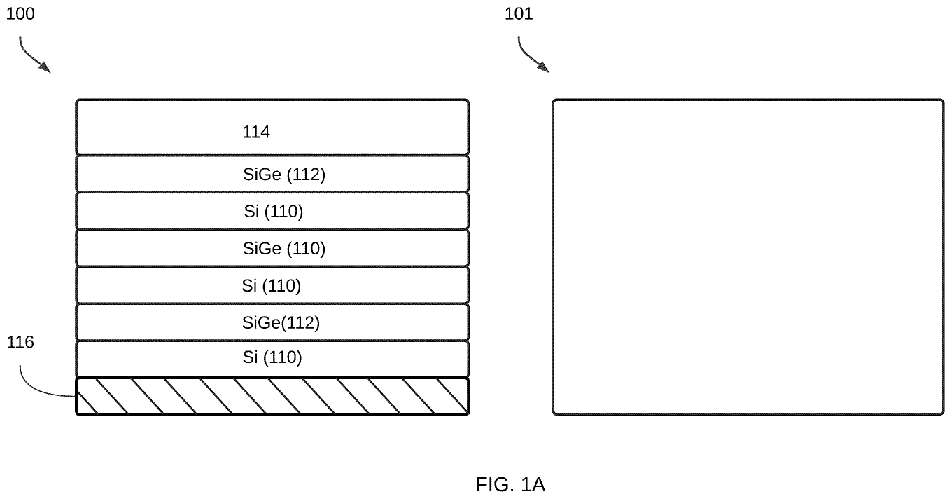

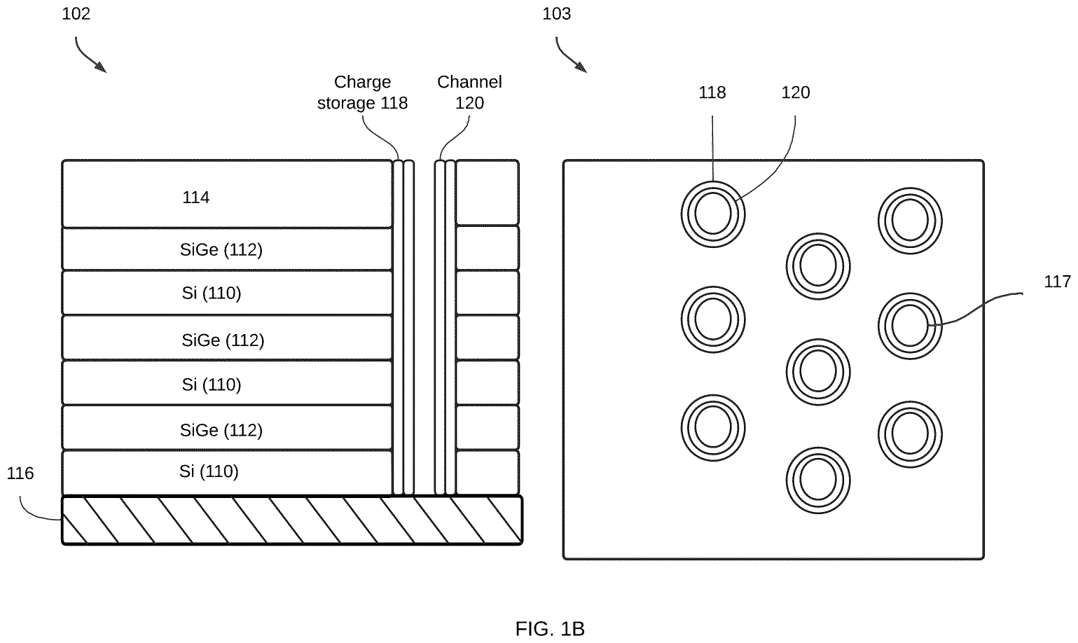

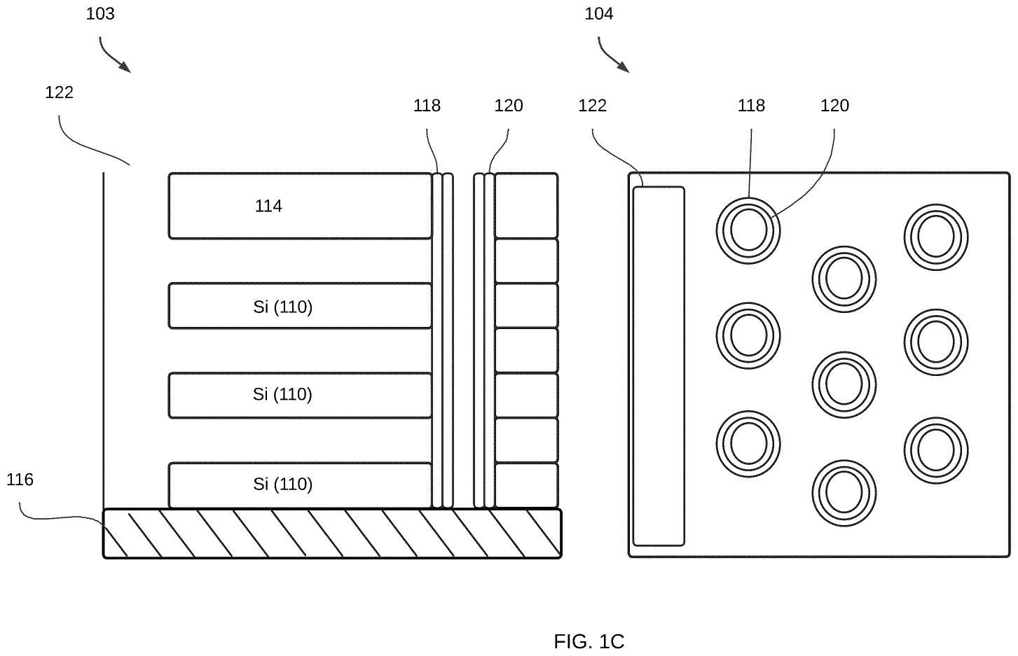

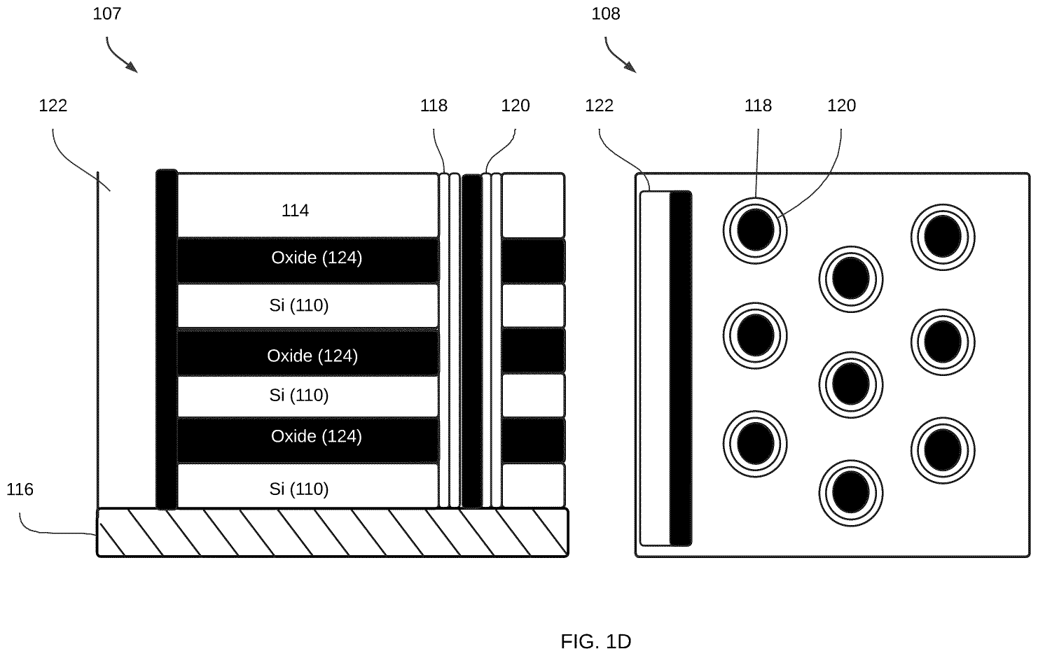

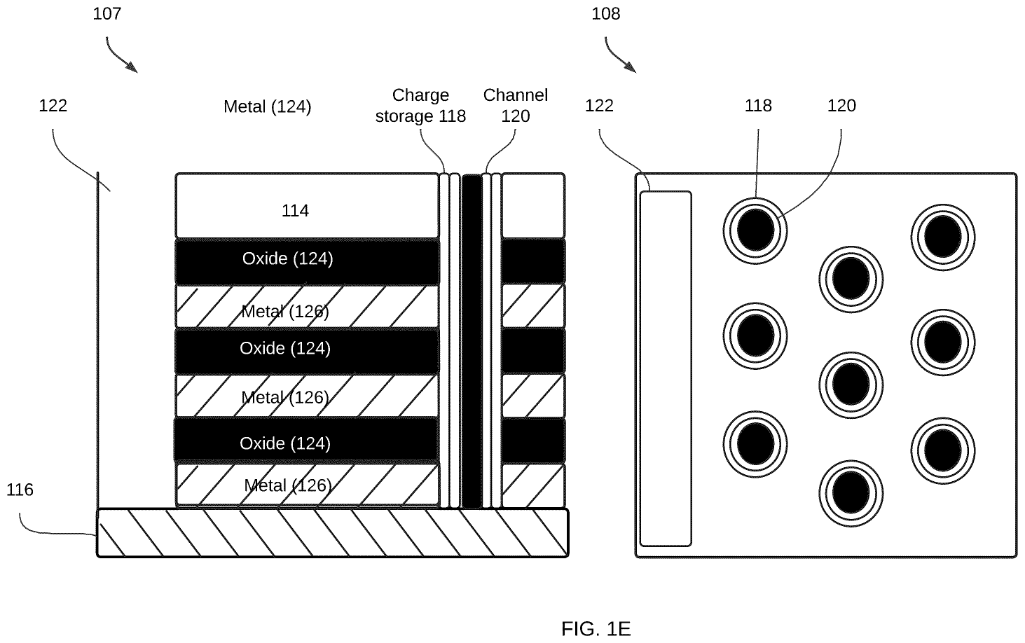

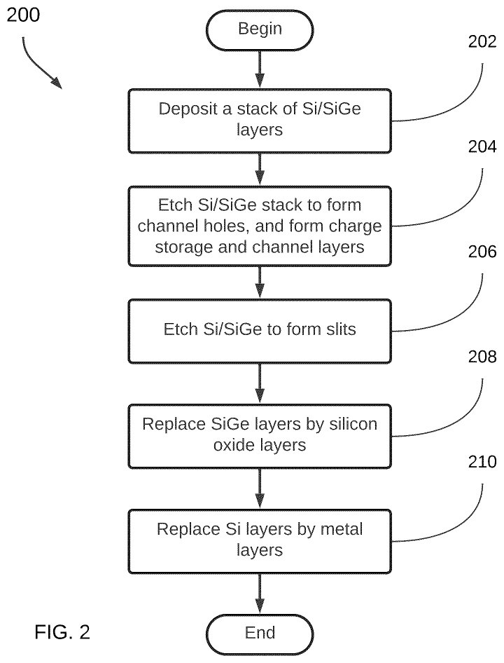

FIGS. 1A to 1E illustrate cross-sectional and top views of the structure at various stages of the process to form the vertical storage unit. FIG. 2 provides a flowchart describing the exemplary process flow. The process is described using these figures to elaborate on the inventive concept.

In Process 200, step 202 involves depositing a stack of multiple Si/SiGe layers. As shown in FIG. 1A, the stack consists of Si layers (110) and SiGe layers (112), deposited onto a substrate layer (116). The cross-sectional view is labeled as 100, and the top view is labeled as 101. The substrate layer 116 may include silicon oxide, silicon nitride, or a combination of both. A cap layer (114), made of silicon oxide or silicon nitride, is deposited optionally on the top of the stack. The Si (110) and SiGe (112) layers may be deposited using plasma-enhanced chemical vapor deposition (PECVD) or thermal CVD techniques. The Si/SiGe are either polycrystalline or amorphous as deposited by the PECVD techniques. Epitaxy techniques may also be used, which creates crystalline Si and SiGe. The epitaxy process requires the substrate layer (116) to be a crystalline Si and SiGe. The SiGe may have a Ge concentration in a range of 10 to 90%. The stack may include 10 to 1000 layers of Si/SiGe pairs.

In step 204, a patterning process is applied to define channel hole areas. A hard mask, such as a carbon layer, is patterned using lithography and etching processes. Afterward, channel holes are formed using a high aspect ratio (HAR) etching process that removes the Si and SiGe layers not covered by the hard mask. The Si and SiGe layers can be etched efficiently using a transformer coupled plasma (TCP) system with halogen-containing process gases, such as fluorine, chlorine, or hydrogen bromide. Following channel hole formation (117 in FIG. 1B), a conformal charge storage layer (118) and channel layer (120) are deposited on the sidewalls of the channel holes. Atomic layer deposition (ALD) is typically used to achieve the necessary conformality. The charge storage layer (118) often includes oxide/silicon nitride, and the channel layer (120) is made of polycrystalline or amorphous silicon. Following the ALD deposition steps, an etching step is often applied to remove the deposited materials at the bottom of the channel holes.

Replacing the ONON stack with a Si/SiGe stack is advantageous, particularly as etching becomes the most significant bottleneck in advancing the 3D NAND roadmap. Etching Si and SiGe is fundamentally faster than etching the ONON stack due to differences in the chemical and physical properties of these materials, especially in bond strength and reactivity.

Si and SiGe are both covalently bonded materials. The Si—Si bonds in pure silicon are relatively easier to break in a plasma or reactive ion etching (RIE) process because their bond energy is significantly lower than that of Si—O or Si—N bonds found in silicon oxide (SiO₂) or silicon nitride (Si₃N₄). SiGe, being an alloy of silicon and germanium, has even lower bond dissociation energy, making it easier to etch than Si. As a result, Si and SiGe etch faster because less energy is required to break their bonds.

In contrast, the ONON stack, consisting of alternating layers of SiO₂ and Si₃N₄, is much harder to etch due to the higher bond dissociation energies of Si—O and Si—N bonds, which require more energy to break. This results in a slower etch process compared to Si or SiGe. Furthermore, SiO₂ and Si₃N₄ are less reactive with etching chemistries, leading to less volatile by-products and a slower removal rate, particularly in high aspect ratio structures.

In step 206 of the process 200, slits are formed through additional patterning and etching processes. In conventional 3D NAND processes, slits are used to replace the silicon nitride layers in an ONON stack with metal gates. In the present embodiment, the slits are used to replace both the Si and SiGe layers. The SiGe layers are replaced with silicon oxide, or simply called oxide throughout this disclosure, which serves as an electrical isolation layer between the metal gates. The metal gates are formed by replacing the Si layers with metal layers. In some embodiments, the metal used is tungsten with a TiN barrier, while in other embodiments, the metal is molybdenum.

The cross-sectional view (103) and top view (104) of the slit (122) are shown in FIG. 1C. Although only one slit is depicted for simplicity, typically two or more slits are placed around an array of channels. After the slit formation, the SiGe layers are removed using a high selectivity etch process against the Si layers and other exposed materials. The SiGe layers can be removed by either dry or wet etching, depending on the selected chemistry, to achieve the high selectivity. The cross-sectional view after SiGe removal is shown as 103 in FIG. 1C.

Going back to Process 200, in step 208, silicon oxide is deposited to fill the gaps left by the removed SiGe layers. ALD is used to achieve void-free gap filling. The cross-sectional view (107) and top view (108) following the silicon oxide deposition are shown in FIG. 1D. The oxide layer is labeled as 124, and the slit 122 is partially filled due to conformality of the ALD process. The silicon oxide deposited onto the sidewalls of the slit 122 will need to be removed for subsequent processing.

In step 210, the Si layers are removed using a high selectivity etch process against silicon oxide and other exposed materials. These layers can be removed by wet or dry etching with carefully selected chemistries. Metal layers are then deposited to fill the gaps between the silicon oxide layers (124). In one embodiment, an aluminum oxide (AlO) layer is first deposited using ALD, followed by the deposition of a tungsten layer using CVD or ALD. A TiN barrier layer may be deposited before tungsten to prevent fluorine penetration during tungsten deposition due to using fluorine containing precursors during the tungsten deposition. Alternatively, a molybdenum layer may be used. The metal on the sidewalls of the slit (122) must be removed to prevent electrical shorts between metal layers. In some implementations, the metal layer will be recessed and a dielectric layer is deposited and etched as a spacer to seal the metal layer.

FIG. 1E shows the cross-sectional view (107) and top view (108) after step 210. The deposition step of the metal layers, labeled as 126, completes the formation of the vertical charge storage units.

It should be noted there are many variants of the present inventive concept. For example, the silicon oxide layer may be used to replace the Si layers instead of SiGe layers, and the metal layers to replace the SiGe layers. All such variants in implementations fall into the scope of the present invention.

1. A method for fabricating vertical storage units of a 3D NAND memory device, comprising:
depositing a stack of alternating silicon (Si) layers and silicon-germanium (SiGe) layers on a substrate;
patterning to define channel holes through a hard mask layer;
forming the channel holes in the stack using an etching process;
forming a charge storage layer and a channel layer on the sidewalls of the channel holes;
creating slits in the stack of Si and SiGe layers through patterning and etching Si and SiGe stack;
removing the SiGe layers through a selective etching process against at least Si layers;
depositing silicon oxide in place of the removed SiGe layers to form electrical isolation layers;
removing the Si layers through a selective etching process against at least the silicon oxide layers;
depositing a metal layer in place of the removed Si layers to form metal gates; and
completing the formation of the vertical charge storage units by removing deposited metals on sidewall of the slit.

2. The method of claim 1, wherein the Si and SiGe layers are deposited using a plasma-enhanced chemical vapor deposition (PECVD) process.

3. The method of claim 1, wherein the Si and SiGe layers are deposited using an epitaxy process.

4. The method of claim 1, wherein the etching processes for removing the Si and SiGe layers during the channel hole and the slit formations are performed using a transformer coupled plasma (TCP) etching system with halogen-containing gases selected from the group consisting of fluorine, chlorine, and hydrogen bromide.

5. The method of claim 1, wherein the charge storage layer is a silicon nitride layer, and the channel layer is a polycrystalline or amorphous silicon layer deposited using atomic layer deposition (ALD) technique.

6. The method of claim 1, wherein the metal layer deposited to replace the Si layers is selected from tungsten or molybdenum.

7. The method of claim 1, wherein the electrical isolation layer formed by replacing the SiGe layers comprises silicon oxide deposited using atomic layer deposition (ALD).

8. The method of claim 1, further comprising depositing a titanium nitride (TiN) barrier layer prior to depositing the metal layer to prevent fluorine penetration into the silicon oxide layer during the metal deposition process.

9. The method of claim 8, wherein the TiN barrier is deposited after an aluminum oxide layer is deposited.

10. The method of claim 1, wherein the removal of the SiGe layers is performed using a wet etching process.

11. The method of claim 1, wherein the removal of the SiGe layers is performed using a dry etching process.

12. The method of claim 1, wherein the removal of the Si layers is performed using a wet etching process.

13. The method of claim 1, wherein the removal of the Si layers is performed using a dry etching process.

14. The method of claim 1, wherein the SiGe layers containing Ge at a concentration between 10% and 90%.

15. The method of claim 1, wherein the stack comprising between 10 and 1000 layers of Si and SiGe pairs.

16. The method of claim 1, wherein the method further includes a step of removing silicon oxide layer deposited on the sidewall of the slit before the silicon layers are removed.
